(19) United States
(12) Patent Application Publication
(10) Pub. No.: US 2013/0196483 A1
(43) Pub. Date: Aug. 1, 2013

(54) SOI STRUCTURES INCLUDING A BURIED BORON NITRIDE DIELECTRIC

(71) Applicants: Robert H. Dennard, Croton on Hudson, NY (US); Alfred Grill, White Plains, NY (US); Effendi Leobandung, Wappingers Falls, NY (US); Deborah A. Neumayer, Danbury, CT (US); Dea-Gyu Park, Hopewell Junction, NY (US); Ghavam G. Shahidi, Pound Ridge, NY (US); Leathen Shi, Yorktown Heights, NY (US)

(72) Inventors: Robert H. Dennard, Croton on Hudson, NY (US); Alfred Grill, White Plains, NY (US); Effendi Leobandung, Wappingers Falls, NY (US); Deborah A. Neumayer, Danbury, CT (US); Dea-Gyu Park, Hopewell Junction, NY (US); Ghavam G. Shahidi, Pound Ridge, NY (US); Leathen Shi, Yorktown Heights, NY (US)

(73) Assignee: International Business Machines Corporation, Armonk, NY (US)

(21) Appl. No.: 13/604,004

(22) Filed: Sep. 5, 2012

Related U.S. Application Data
(63) Continuation of application No. 13/359,110, filed on Jan. 26, 2012.

(51) Int. Cl. H01L 21/30

(52) U.S. Cl. 438/458; 257/E21.211

(57) ABSTRACT

Boron nitride is used as a buried dielectric of an SOI structure including an SOI layer and a handle substrate. The boron nitride is located between an SOI layer and a handle substrate. Boron nitride has a dielectric constant and a thermal expansion coefficient close to silicon dioxide. Yet, boron nitride has a wet as well as a dry etch resistance that is much better than silicon dioxide. In the SOI structure, there is a reduced material loss of boron nitride during multiple wet and dry etches so that the topography and/or bridging are not an obstacle for device integration. Boron nitride has a low dielectric constant so that devices built in SOI active regions do not suffer from a charging effect.

### CROSS REFERENCE TO RELATED APPLICATION

This application is a continuation of U.S. patent application Ser. No. 13/359,110, filed Jan. 26, 2012 the entire content and disclosure of which is incorporated herein by reference.

### BACKGROUND

The present disclosure relates to semiconductor-on-insulator (SOI) structures, and particularly to SOI structures in which a buried boron nitride dielectric is located between a top semiconductor layer and a handle substrate.

Advanced semiconductor-on-insulator (SOI) circuits employ a thin top semiconductor layer, or a “semiconductor-on-insulator” (SOI) layer to provide enhanced performance. Presently, SOI wafers use silicon dioxide as a buried dielectric that is located beneath the SOI layer. The silicon dioxide is typically referred to as a “buried oxide” or “BOX”.

When extremely thin semiconductor-on-insulator (ETSOI) field effect transistors (FETs) are built on a mesa cut from an SOI layer without the presence of a shallow trench isolation (STI) structure, undercuts and notches are typically formed in the BOX around the SOI mesa. The aforementioned undercuts or notches serve as a bridging or shorting path for devices such as, for example, FinFETs or nanowire FETs, that are subsequently formed using the SOI mesa as an element of the device.

In view of the above, there is a need for providing SOI structures in which the formation of undercuts and notches in the buried dielectric around the SOI mesa is substantially reduced or even eliminated so that topography and/or bridging will not become obstacles for device integration.

### SUMMARY

Boron nitride is used in the present disclosure as a buried dielectric of an SOI structure including an SOI layer and a handle substrate. The boron nitride is located between the SOI layer and the handle substrate. Boron nitride has a dielectric constant and a thermal expansion coefficient close to silicon dioxide. Yet, and unlike silicon dioxide, boron nitride has a wet as well as dry etch resistance that is much better than silicon dioxide. Typically, boron nitride has a wet etch resistance and a dry etch resistance that is close to, or sometimes even better than, silicon nitride; silicon nitride has been proposed to be a possible replacement candidate for silicon dioxide.

In the SOI structure of the present disclosure, there is a reduced material loss of boron nitride during multiple wet and dry etches so that the topography and/or bridging is not an obstacle for device integration. Moreover, boron nitride has a low dielectric constant so that devices built in SOI active regions do not suffer from a charging effect.

In one aspect of the present disclosure, an SOI structure is provided. The SOI structure of the present disclosure includes a handle substrate comprising a first semiconductor material. A layer of boron nitride is located atop the handle substrate, and an SOI layer comprising a second semiconductor material is located atop the layer of boron nitride.

In one embodiment, a layer of insulating oxide can be located between the handle substrate and the layer of boron nitride. In another embodiment, a layer of insulating oxide can be located between the layer of boron nitride and the SOI layer. In a further embodiment, a layer of insulating oxide can be located between the handle substrate and the layer of boron nitride and another layer of insulating oxide can be located between the layer of boron nitride and the SOI layer.

In another aspect of the present disclosure, an SOI structure including at least one SOI mesa is provided. In this aspect of the present disclosure, the SOI structure includes a handle substrate comprising a first semiconductor material. A layer of boron nitride is located atop the handle substrate, and at least one SOI mesa is located atop the layer of boron nitride. The at least one SOI mesa has vertical sidewall edges that do not extend beyond, and are not vertically aligned to, vertical sidewall edges of the layer of boron nitride.

In one embodiment, a layer of insulating oxide can be located between the handle substrate and the layer of boron nitride. In another embodiment, a layer of insulating oxide can be located between the layer of boron nitride and the at least one SOI mesa. In a further embodiment, a layer of insulating oxide can be located between the handle substrate and the layer of boron nitride and another layer of insulating oxide can be located between the layer of boron nitride and the SOI mesa.

In a further aspect of the present disclosure, methods of fabricating an SOI structure including a buried layer of boron nitride are provided. In one embodiment, the method of the present disclosure includes: providing a handle substrate comprising a first semiconductor material; providing a layer of boron nitride atop a surface of a semiconductor wafer comprising a second semiconductor material; bonding the handle substrate to the layer of boron nitride to provide a bonded structure in which the semiconductor wafer represents a topmost layer of the bonded structure and the handle substrate represents a bottommost layer of the bonded substrate; and removing a portion of the semiconductor wafer to provide a semiconductor-on-insulator (SOI) layer of a silicon-on-insulator (SOI) structure, the SOI structure comprising the handle substrate, the layer of boron nitride located atop the handle substrate, and the SOI layer located atop the layer of boron nitride.

In another embodiment, the method of fabricating the SOI substrate includes providing a layer of insulating oxide on a surface of a handle substrate comprising a first semiconductor material; providing a layer of boron nitride atop a surface of a semiconductor wafer comprising a second semiconductor material; bonding the layer of insulating oxide to the layer of boron nitride to provide a bonded structure in which the semiconductor wafer represents a topmost layer of the bonded structure and the handle substrate represents a bottommost layer of the bonded substrate; and removing a portion of the semiconductor wafer to provide a semiconductor-on-insulator (SOI) layer of a silicon-on-insulator (SOI) structure, the SOI structure comprising the handle substrate, the layer of insulating oxide located on an uppermost surface of the handle substrate, the layer of boron nitride located on an uppermost surface of the layer of insulating oxide and the SOI layer located atop the layer of boron nitride.

### BRIEF DESCRIPTION OF THE DRAWINGS

FIG. 1 is a pictorial representation (through a cross-sectional view) depicting an SOI structure in accordance with an embodiment of the present disclosure.

FIG. 2 is a pictorial representation (through a cross sectional view) depicting another SOI structure in accordance with another embodiment of the present disclosure.

FIG. 3 is a pictorial representation (through a cross sectional view) depicting yet another SOI structure in accordance with yet another embodiment of the present disclosure.

FIG. 4 is a pictorial representation (through a cross sectional view) depicting still yet another SOI structure in accordance with still yet another embodiment of the present disclosure.

FIG. 5 is a pictorial representation (through a cross sectional view) depicting an SOI structure of the present disclosure including at least one SOI mesa.

FIG. 6 is a pictorial representation (through a cross sectional view) depicting another SOI structure of the present disclosure including at least one SOI mesa.

FIG. 7 is a pictorial representation (through a cross sectional view) depicting yet another SOI structure of the present disclosure including at least one SOI mesa.

FIG. 8 is a pictorial representation (through a cross sectional view) depicting still yet another SOI structure of the present disclosure including at least one SOI mesa.

FIG. 9 is a pictorial representation (through a cross sectional view) illustrating the formation of an optional layer of insulating oxide on a handle substrate in accordance with an embodiment of the present disclosure.

FIG. 10 is a pictorial representation (through a cross sectional view) illustrating the formation of a layer of boron nitride and an optional layer of another insulating oxide on a semiconductor wafer and optionally implanting hydrogen into the semiconductor wafer in accordance with an embodiment of the present disclosure.

FIG. 11 is a pictorial representation (through a cross sectional view) illustrating the structures of FIGS. 9 and 10 after rotating the structure of FIG. 10 by 180° and positioning the rotated structure of FIG. 10 atop the structure of FIG. 9.

FIG. 12 is a pictorial representation (through a cross sectional view) illustrating the structures of FIG. 11 after bonding.

FIG. 13 is a pictorial representation (through a cross sectional view) illustrating the bonded structure of FIG. 12 after removing a portion of the semiconductor wafer providing an SOI structure of the present disclosure including a layer of boron nitride positioned between the SOI layer and the handle substrate.

FIG. 14 is a pictorial representation (through a cross sectional view) illustrating the structure of FIG. 13 after removing selective portions of the SOI layer forming at least one SOI mesa.

### DETAILED DESCRIPTION

The present disclosure will now be described in greater detail by referring to the following discussion and drawings that accompany the present disclosure. It is noted that the drawings of the present disclosure are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present disclosure. However, it will be appreciated by one of ordinary skill in the art that the various embodiments of the present disclosure may be practiced without these specific details. In other instances, well-known structures or processing steps have not been described in detail in order to avoid obscuring the present disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present.

As stated above, the present disclosure provides an SOI structure that includes a layer of boron nitride located between a top semiconductor layer and a handle substrate. The layer of boron nitride substantially replaces the buried oxide layer of prior art SOI structures. As such, the SOI structures of the present disclosure advantageously exhibit less material loss of the layer of boron nitride during multiple etching processes, without increasing the overall dielectric constant of the SOI structure. As a consequence of using boron nitride instead of silicon dioxide, the SOI structures of the present disclosure do not exhibit any topographical and/or bridging issues that may lead to obstacles during device integration. Moreover, the SOI structures of the present disclosure do not suffer from a charging effect. By “charging effect” it is meant the electrostatic charges, i.e., electrons or holes, induced in the active regions by the presence of a high dielectric constant (k greater than 4.0) material.

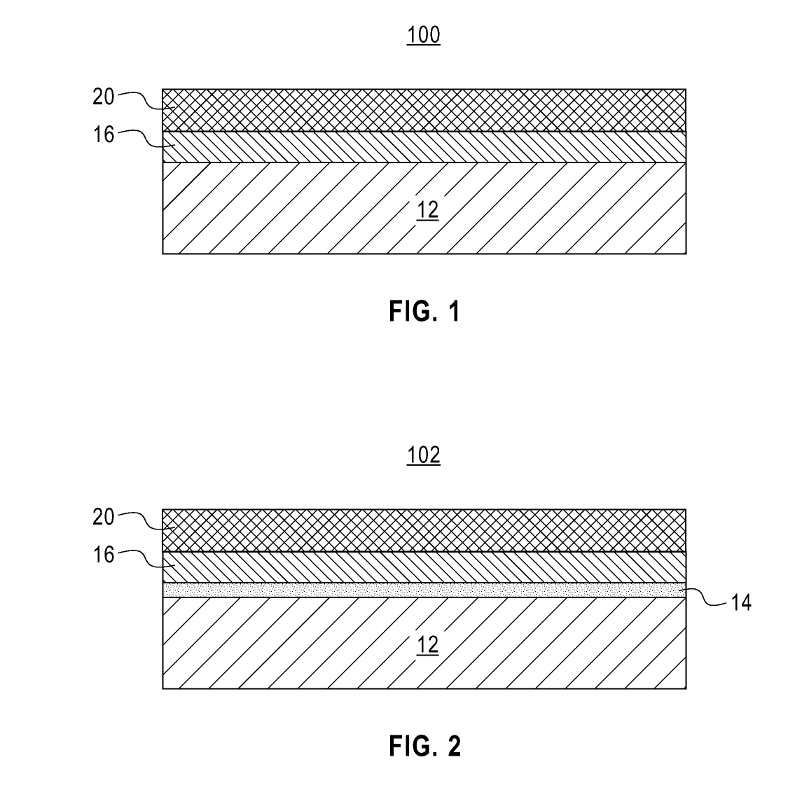

Reference is now made to FIGS. 1-8 which show some exemplary SOI structures of the present disclosure. Specifically, FIG. 1 illustrates an exemplary SOI structure 100 of the present disclosure that includes, from bottom to top, a handle substrate 12 comprising a first semiconductor material, a layer of boron nitride 16 located on an uppermost surface of the handle substrate 12, and a semiconductor-on-insulator (SOI) layer 20 comprising a second semiconductor material located on an uppermost surface of the layer of boron nitride 16.

Specifically, FIG. 2 illustrates another exemplary SOI structure 102 of the present disclosure that includes, from bottom to top, a handle substrate 12 comprising a first semiconductor material, a layer of insulating oxide 14 located on an uppermost surface of the handle substrate 12, a layer of boron nitride 16 located on an uppermost surface of the layer of insulating oxide 14, and a semiconductor-on-insulator (SOI) layer 20 comprising a second semiconductor material located on an uppermost surface of the layer of boron nitride 16.

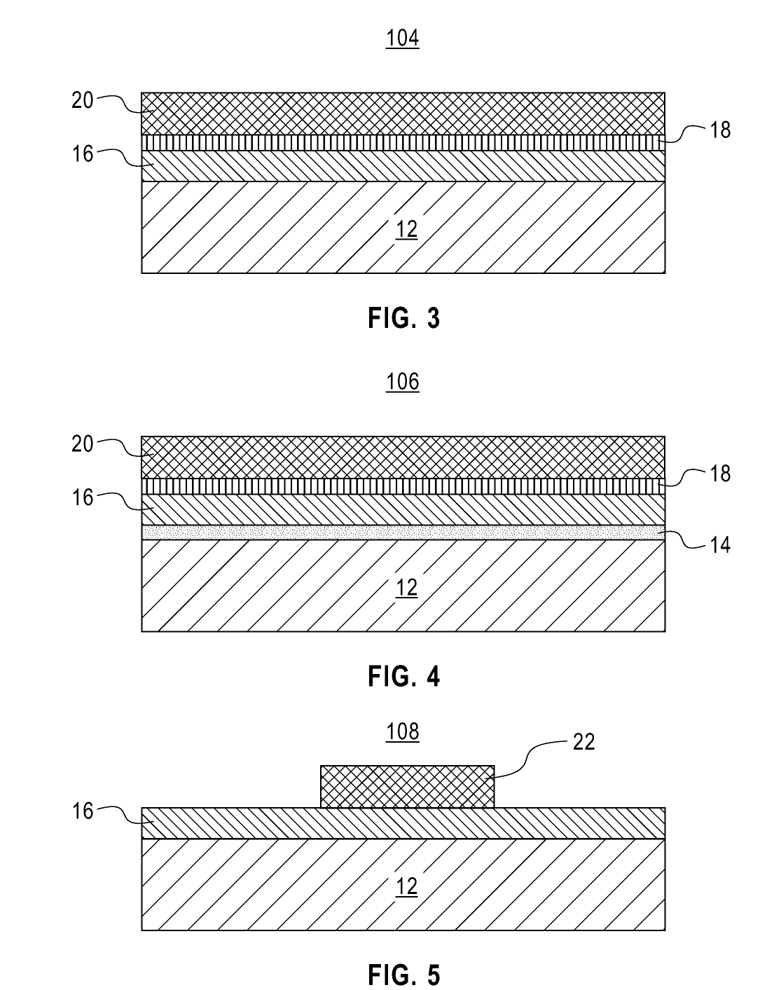

FIG. 3 illustrates yet another exemplary SOI structure 104 of the present disclosure that includes, from bottom to top, a handle substrate 12 comprising a first semiconductor material, a layer of boron nitride 16 located on an uppermost surface of the handle substrate 12, a layer of insulating oxide 18 located on an uppermost surface of the layer of boron nitride 16 and a semiconductor-on-insulator (SOI) layer 20 comprising a second semiconductor material located on an uppermost surface of the layer of insulating oxide 18.

FIG. 4 illustrates still yet another exemplary SOI structure 106 of the present disclosure that includes, from bottom to top, a handle substrate 12 comprising a first semiconductor material, a layer of insulating oxide 14 located on an uppermost surface of the handle substrate 12, a layer of boron nitride 16 located on an uppermost surface of the a layer of insulating oxide 14, another layer of insulating oxide 18 located on an uppermost surface of the layer of boron nitride and a semiconductor-on-insulator (SOI) layer 20 comprising a second semiconductor material located on an uppermost surface of the layer of insulating oxide 18.

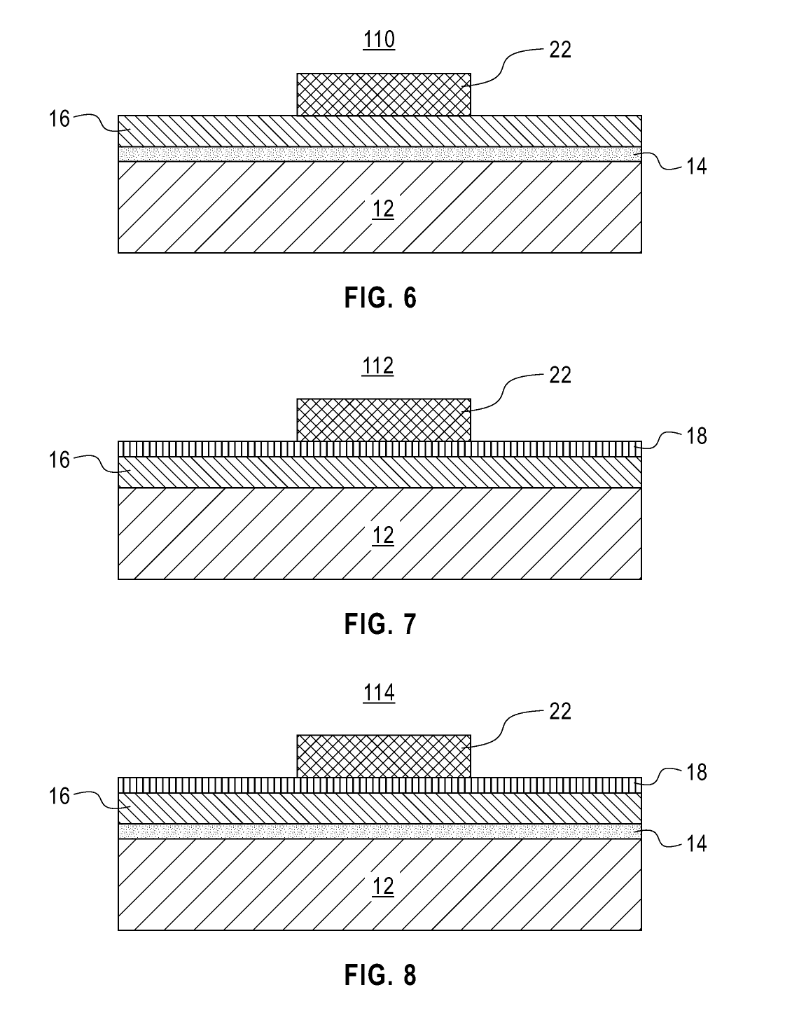

FIG. 5 illustrates a further exemplary SOI structure 108 which is identical to the exemplary SOI structure 100 of FIG. 1 except that the SOI layer that is located above the layer of boron nitride 16 has been patterned into at least one SOI mesa 22. FIG. 6 illustrates a yet further exemplary SOI structure 110 which is identical to the exemplary SOI structure 102 of FIG. 2 except that the SOI layer that is located above the layer of boron nitride 16 has been patterned into at least one SOI mesa 22. FIG. 7 illustrates a still further exemplary SOI structure 112 which is identical to the exemplary SOI structure 104 of FIG. 3 except that the SOI layer that is located above the layer of insulating oxide 18 has been patterned into at least one SOI mesa 22. FIG. 8 illustrates an even further exemplary SOI structure 114 which is identical to the exemplary SOI structure 106 of FIG. 4 except that the SOI layer that is located above the layer of insulating oxide 18 has been patterned into at least one SOI mesa 22.

The elements mentioned above for each of the exemplary SOI structures (100, 102, 104, 106, 108, 110, 112 and 114) of the present disclosure are now described in greater detail. Each exemplary SOI structure (100, 102, 104, 106, 108, 112 and 114) includes a handle substrate 12. The handle substrate 12 that is employed in the present disclosure includes a first semiconductor material which can be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials.

In some embodiments of the present disclosure, the material of the handle substrate 12 can be a single crystalline, i.e., epitaxial, semiconductor material. The term “single crystalline” as used throughout the present disclosure denotes a material in which the crystal lattice of the entire sample is continuous and unbroken to the edges of the sample, with no grain boundaries. In one example, the handle substrate 12 can be a single crystalline silicon material. In other embodiments of the present disclosure, the material of the handle substrate 12 may be amorphous. By “amorphous” it is meant a material that lacks the long-range order characteristic of a crystal. In a further embodiment of the present disclosure, the material of the handle substrate 12 can be polycrystalline. By “polycrystalline” it is meant a material that is composed of many crystallites of varying size and orientation. The variation in direction can be random (called random texture) or directed, possibly due to growth and processing conditions.

All or portions of the handle substrate 12 can be doped to provide at least one globally or locally conductive region (not shown) located beneath the interface between the handle substrate 12 and the layer of insulating oxide 14 or the layer of boron nitride 16. The dopant concentration in doped regions of the handle substrate 12 can be optimized for device performance. The thickness of the handle substrate 12 can be from 50 microns to 1 mm, although lesser and greater thicknesses can also be employed.

In some of the SOI structures of the present disclosure, a layer of insulating oxide 14 is present atop the handle substrate 12. In accordance with the present disclosure, the layer of insulating oxide 14 is optionally employed. The optional layer of insulating oxide 14 includes an oxide and a semiconductor, which may or may not be the same as the semiconductor material of the underlying handle substrate 12. Typically, but not necessarily always, the optional layer of insulating oxide 14 is an oxide of the underlying semiconductor material. Examples of insulating oxides that can be employed as the layer of insulating oxide 14 include, but are not limited to, silicon oxide (i.e., silicon dioxide), silicon germanium oxide, and an oxide of a silicon carbon alloy. In one embodiment of the present disclosure, the optional layer of insulating oxide 14 is silicon oxide (i.e., silicon dioxide). In some embodiments, the optional layer of insulating oxide 14 is a thermal insulating oxide that is formed utilizing a thermal oxidation process.

When present, the thickness of the optional layer of insulating oxide 14 is less than the thickness of a conventional buried oxide of a conventional SOI structure. In one embodiment of the present disclosure, the optional layer of insulating oxide 14 has a thickness from 5 nm to 10 nm. In another embodiment, the optional layer of insulating oxide 14 has a thickness from 2 nm to 5 nm. The presence of the optional layer of insulating oxide 14 serves to provide a good adhesion interface between the handle substrate 12 and the layer of boron nitride layer 16 and to plug any pin holes in as well as to absorb volatile species coming from the deposited boron nitride.

Each of the SOI structures of the present disclosure also includes a layer of boron nitride 16. In accordance with the present disclosure, the layer of boron nitride 16 is located between the handle substrate 12 and the SOI layer 20 or SOI mesa 22. In one embodiment, the layer of boron nitride 16 is located directly on an uppermost surface of the handle substrate 12. In another embodiment, the layer of boron nitride 16 is located directly on an uppermost surface of the layer of insulating oxide 14. In some embodiments of the present disclosure, an uppermost surface of the layer of boron nitride 16 is in direct contact with a bottommost surface of an overlying SOI layer 20 or SOI mesa 22. In other embodiments of the present disclosure, an uppermost surface of the layer of boron nitride 16 is in direct contact with a bottommost surface of another layer of insulating oxide 18.

Boron nitride is a chemical compound with the chemical formula BN, consisting of equal numbers of boron and nitrogen atoms. BN is isoelectronic to a similarly structured carbon lattice and thus it can exist in various crystalline forms. In one embodiment of the present disclosure, the layer of boron nitride 16 includes boron nitride that is in a hexagonal form. In another embodiment, the layer of boron nitride 16 includes boron nitride that is in a cubic form.

The layer of boron nitride 16 that is employed in the present disclosure has a dielectric constant that can be less than 5.0. In one embodiment of the present disclosure the layer of boron nitride 16 has a dielectric constant of 3.64.

The layer of boron nitride 16 that is employed in the present disclosure has a good selectivity for wet etches. In one embodiment of the present disclosure, the layer of boron nitride 16 has an etch selectivity of from 25 to 65 in a 100:1 DHF etchant as compared to silicon dioxide. In another embodiment of the present disclosure, the layer of boron nitride 16 has an etch selectivity of from 4.4 to 6.8 in hot (180° C.) phosphoric acid as compared to silicon nitride.

The layer of boron nitride 16 that is employed in the present disclosure also has a good selectivity for dry etches. In some embodiments, the layer of boron nitride 16 has a good plasma resistance. By “good plasma resistance” it is meant that the material can withstand plasma bombardment and etching without a significant loss of material. In some embodiments of the present disclosure, the layer of boron nitride 16 can be tuned to achieve a much lower etch rate in comparison with the etch rates on other dielectrics, e.g., silicon dioxide or silicon nitride, by optimizing the associated reactive ion etching process.

In one embodiment, the thickness of the layer of boron nitride 16 can be from 10 nm to 50 nm. In another embodiment of the present disclosure, the thickness of the layer of boron nitride 16 can be from 50 nm to 200 nm.

In some embodiments of the present disclosure, the SOI structures can also include an optional layer of insulating oxide 18. In some embodiments, the optional layer of insulating layer 18 can be used as the sole insulating oxide present in the structure. In other embodiments, the optional layer of insulating oxide 18 can be present in the structure together with the optional insulating oxide layer 14. In such an embodiment, the optional layer of insulating oxide 18 can be referred to as another layer of insulating oxide. When the optional layer of insulating oxide 18 is present, the optional layer of insulating oxide 18 is located on an uppermost surface of the layer of boron nitride 16. The optional layer of insulating oxide 18 is typically used in embodiments in when a nitride reactive ion etching process is used in a subsequently processing step during formation of a semiconductor device.

The optional layer of insulating oxide 18 that can be optionally employed in the present disclosure includes one of the insulating oxide materials mentioned above for the optional layer of insulating oxide 14. In one embodiment of present disclosure and when both the optional layers of insulating oxide are present, the optional layer of insulating oxide 18 includes a same insulating oxide material as that of the layer of insulating oxide layer 14. In another embodiment of present disclosure and when both optional layers of insulating oxide are present, the another layer of insulating oxide 18 includes a different insulating oxide material as that of the layer of insulating oxide layer 14.

In one embodiment of the present disclosure, the optional layer of insulating oxide 18 has a thickness from 1 nm to 5 nm. In another embodiment, the optional layer of insulating oxide 18 has a thickness from 5 nm to 10 nm.

The SOI structures of the present disclosure either include a semiconductor-on-insulator (SOI) layer 20 or a SOI mesa 22. It is noted that the SOI mesa 22 that is employed in some embodiments of the present disclosure includes a remaining portion of the SOI layer that is not removed by etching. The SOI layer 20 is a contiguous layer that spans across the entirety of the SOI structure, while the SOI mesa 22 is a semiconductor island that has vertical sidewall edges that do not extend beyond, and are not vertically aligned to, vertical sidewall edges of the layer of boron nitride 16.

The SOI layer 20 and the SOI mesa 22 each comprises a second semiconductor material which can be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. In some embodiments of the present disclosure, the second semiconductor material of the SOI layer 20 or the SOI mesa 22 can be a single crystalline, i.e., epitaxial, semiconductor material. In one example, the second semiconductor material of the SOI layer 20 or the SOI mesa 22 can be a single crystalline silicon material. In other embodiments of the present disclosure, the second semiconductor material of the SOI layer 20 or the SOI mesa 22 may be amorphous. In a further embodiment of the present disclosure, the second semiconductor material of the SOI layer 20 or the SOI mesa 22 can be polycrystalline.

In one embodiment, the second semiconductor material of the SOI layer 20 or the SOI mesa 22 may be comprised of a same semiconductor material as that of the handle substrate 12. In another embodiment, the second semiconductor material of the SOI layer 20 or the SOI mesa 22 may be comprised of a different semiconductor material as that of the handle substrate 12.

All or portions of the SOI layer 20 and/or the SOI mesa 22 can be doped to provide at least one globally or locally conductive region (not shown). The dopant concentration in doped regions of the SOI layer 20 and or the SOI mesa 22 can be optimized for device performance.

In one embodiment, the thickness of the SOI layer 20 and or the SOI mesa 22 can be from 5 nm to 15 nm. In another embodiment, the thickness of the SOI layer 20 and or the SOI mesa 22 can be from 15 nm to 35 nm. The SOI mesa 22 may include a single mesa structure, or a plurality of mesa structures can be located atop the layer of boron nitride 16. The width of each SOI mesa 22 may vary depending on the conditions of the lithographic process used to pattern the same and the type of resultant device being fabricating therefrom. In one embodiment, the width of the SOI mesa 22, as measured from one vertical sidewall edge to another vertical sidewall edge, is from 5 nm to 25 nm. In another embodiment, the width of the SOI mesa 22, as measured from one vertical sidewall edge to another vertical sidewall edge, is from 25 nm to 100 nm.

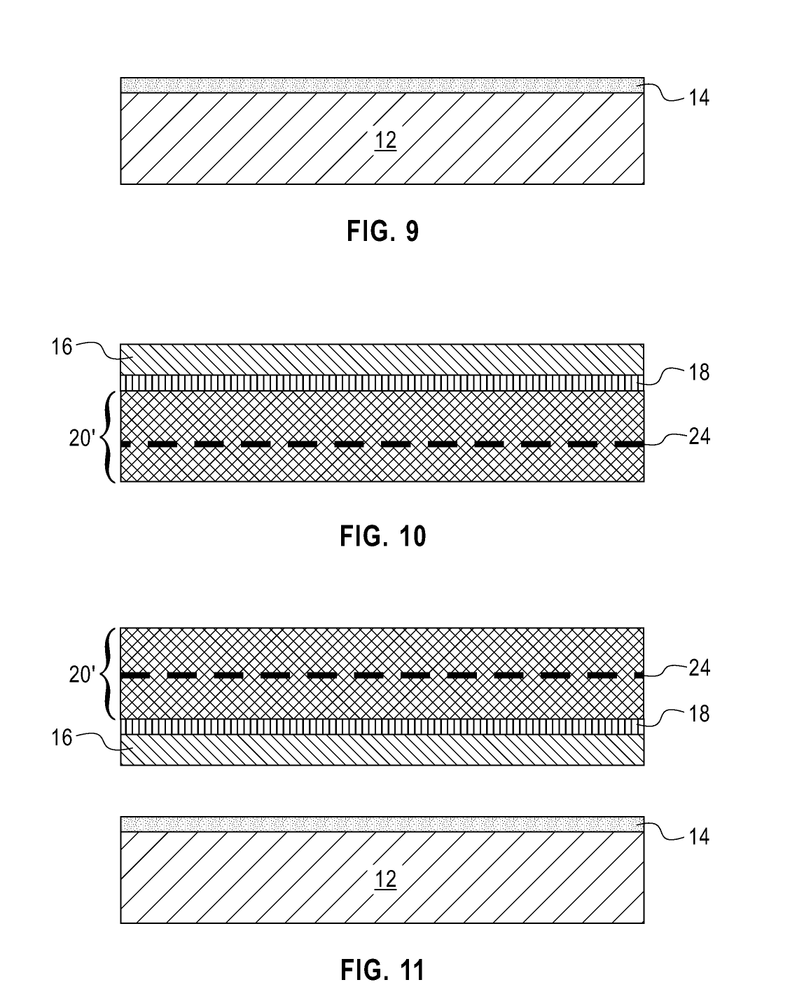

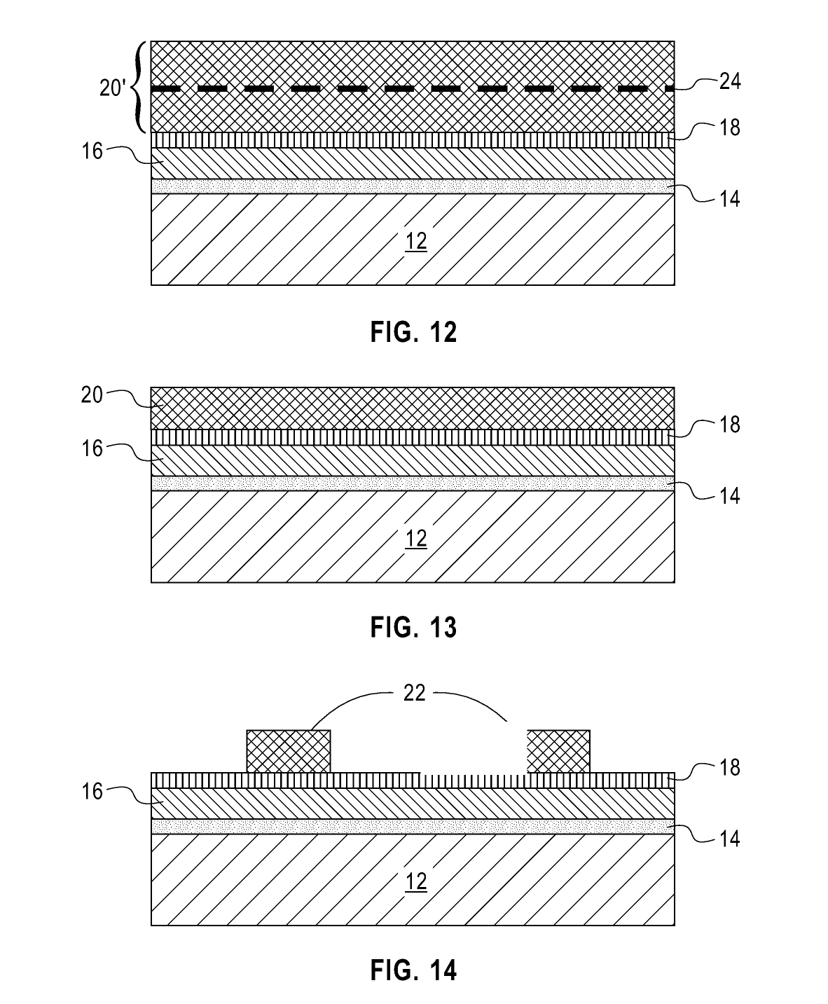

Reference is now made to FIGS. 9-14 which provide a method in accordance with an embodiment of the present disclosure. The method of present disclosure includes providing a layer of insulating oxide 14 on a surface of a handle substrate 12 comprising a first semiconductor material (See FIG. 9); providing a layer of boron nitride 16 atop a surface of a semiconductor wafer 20′ comprising a second semiconductor material (See FIG. 10); bonding the layer of insulating oxide 14 to the layer of boron nitride 16 to provide a bonded structure in which the semiconductor wafer 20′ represents a topmost layer of the bonded structure and the handle 12 represents a bottommost layer of the bonded substrate (See FIGS. 11-12); and removing a portion of the semiconductor wafer 20′ to provide a semiconductor-on-insulator (SOI) layer 20 of a silicon-on-insulator (SOI) structure (See FIG. 13).

FIG. 14 shows the structure of FIG. 13 after removing a portion of the SOI layer 20 forming at least one SOI mesa 22 atop the layer of boron nitride 16. Details of the method of the present disclosure will now be described in greater detail. Details concerning the materials and other properties of the elements depicted in FIGS. 9-14 that have the same reference numerals as illustrated in FIGS. 1-8 are as described above.

Referring first to FIG. 9, there is depicted a first structure that can be employed in the present disclosure. The first structure shown in FIG. 9 includes a layer of insulating oxide 14 on a handle substrate 12. The layer of insulating oxide 14 can be formed utilizing a thermal oxidation process. Alternatively, the layer of insulating oxide 14 can be formed utilizing a conventional deposition process such as, but not limited to, chemical vapor deposition (CVD), plasma enhanced chemical vapor deposition (PECVD), evaporation, and chemical solution deposition. In some embodiments of the present disclosure, the layer of insulating oxide 14 is not formed atop the handle substrate 12.

Referring now to FIG. 10, there is illustrated a second structure that can be employed in the present disclosure. The second structure shown in FIG. 10 includes a semiconductor wafer 20′ comprising a second semiconductor material, an optional another layer of insulating oxide 18 and a layer of boron nitride 16. The second structure also includes an optional hydrogen implant region 24 that is formed into the semiconductor wafer 20′ after providing the layer of boron nitride 16 and optionally the another layer of insulating oxide 18. In accordance with the present disclosure, the semiconductor wafer 20′ comprises one of the semiconductor materials mentioned above for the SOI layer 20 or SOI mesa 22. It is noted that at least a portion of the semiconductor wafer 20′ will be used in the present disclosure as the SOI layer 20 or SOI mesa 22 of the SOI structure.

The optional another layer of insulating oxide 18 that can be present in the second structure can be formed utilizing one of the techniques mentioned above that was used in forming the layer of insulating oxide 14 in the first structure that is illustrated in FIG. 9. As shown, the another layer of insulating oxide 18 is located on an uppermost surface of the semiconductor wafer 20′. In some embodiments of the present disclosure, the another layer of insulating oxide 18 is not used. In other embodiments, the another layer of insulating oxide 18 will represent the only insulating oxide layer present in the final SOI structure.

The layer of boron nitride 16 which can be formed either directly on the uppermost surface of the optional another semiconductor layer 18 or directly on the uppermost surface of the semiconductor wafer 20′ can be formed by deposition. Examples of deposition processes that can be used in forming the layer of boron nitride include, but are not limited to, CVD, PECVD, atomic layer deposition (ALD) and plasma enhanced atomic layer deposition (PE_ALD).

In some embodiments of the present disclosure, the layer of boron nitride 16 can be deposited from a single boron nitride precursor. In other embodiments of the present disclosure, the layer of boron nitride 16 can be deposited from multiple boron nitride precursors. Illustrative examples of boron nitride precursors that can be employed include, but are not limited to, diborane and ammonia and/or/nitrogen (B₂H₆+NH₃/N₂), trialkylamine boranes (such as, for example, triethylamine borane) and ammonia and/or/nitrogen, and borazine ((BN)₃(NH₃)=B₃N₃H₆) and N₂ or NH₃.

In embodiments in which PECVD is employed in forming the layer of boron nitride 16, the PECVD can be performed at a temperature from 250° C. to 450° C., with a temperature from 300° C. to 400° C. being more typical. The deposition pressure that can be employed when PECVD is employed in forming the layer of boron nitride 16 is typically from 1 Torr to 10 Torr.

Atomic layer deposition (ALD) and plasma enhanced atomic layer deposition (PE_ALD) are thin film deposition techniques that are based on the sequential use of a gas phase chemical process. The majority of ALD and PE_ALD reactions use two precursors. These precursors react with a surface one-at-a-time in a sequential manner. By exposing the precursors to the growth surface repeatedly, a thin film is deposited. ALD and PE_ALD are self-limiting (the amount of film material deposited in each reaction cycle is constant), sequential surface chemistry that deposits comformal thin films of materials onto substrates of varying compositions. ALD (and PE_ALD) is similar in chemistry to CVD (PECVD), except that the ALD reaction breaks the CVD reaction into two half-reactions keeping the precursor materials separate during the reaction. Due to the characteristics of self-limiting and surface reactions, ALD film growth makes atomic scale deposition control possible. Separation of the precursors is accomplished by pulsing a purge gas (typically nitrogen or argon) after each precursor pulse to remove excess precursor from the process chamber and prevent ‘parasitic’ CVD deposition on the substrate.

The growth of the layer of boron nitride 16 by ALD or PE_ALD can include the following characteristic four steps: 1) Exposure of the first precursor. 2) Purge or evacuation of the reaction chamber to remove the non-reacted precursors and the gaseous reaction by-products. 3) Exposure of the second precursor—or another treatment to activate the surface again for the reaction of the first precursor. 4) Purge or evacuation of the reaction chamber. The precursors used in ALD and PE-ALD can include the precursors mentioned above for forming layer of boron nitride 16. In some embodiments of the present disclosure in which ALD is employed in forming the layer of boron nitride 16, the atomic layer deposition can be performed at a temperature from 20° C. to 500° C., with a temperature of from 50° C. to 300° C. being more typical. The deposition pressure that can be employed when atomic layer deposition is employed in forming the layer of boron nitride 16 is typically from 0.1 Torr to 100 Torr.

In some embodiments of the present disclosure, an anneal follows the formation of the layer of boron nitride 16 atop the semiconductor wafer 20′. When an anneal follows the formation of the layer of boron nitride 16, the anneal can be performed at a temperature from 900° C. to 1250° C. in an oxygen free ambient. By “oxygen free ambient” it is meant that no oxygen is present in the ambient. In one embodiment, the oxygen free ambient includes an inert gas such as, for example, helium, argon, neon and mixtures thereof.

In some embodiments, the layer of boron nitride 16 is subjected to a planarization process such as, for example, chemical mechanical polishing and/or grinding, to provide a layer of boron nitride that has a surface roughness (i.e., Rms) of less than 5 Å. Such a low surface roughness may be required in some bonding methods that can be subsequently used to bond the structures shown in FIGS. 9 and 10.

In yet other embodiments of the present disclosure, a hydrogen implant is performed through the layer of boron nitride 16 and the optional another layer of insulating oxide 18 stopping at a depth of from 50 nm to 150 nm beneath the uppermost surface of the semiconductor wafer 20′. In FIG. 10, the doted line labeled as element 24 denotes a hydrogen implant region that is formed into the semiconductor wafer 20′.

Referring now to FIG. 11, there is illustrated the structures of FIGS. 9 and 10 after rotating the structure of FIG. 10 by 180° and positioning the rotated structure of FIG. 10 atop the structure of FIG. 9. In one embodiment, the rotating and positioning of the structures can be performed mechanically. In another embodiment, the rotating and positioning of the structures can be performed by hand.

Referring now to FIG. 12, there is illustrated the structures of FIG. 11 after bonding the layer of insulating oxide 14 of the first structure to the layer of boron nitride 16 of the second structure. In some embodiments in which the layer of insulating oxide 14 is not present, bonding will occur between the uppermost surface of the handle substrate 12 and the layer of boron nitride 16 of the second structure. Bonding provides a bonded structure in which the semiconductor wafer 20′ represents a topmost layer of the bonded structure and the handle substrate 12 represents a bottommost layer of the bonded substrate. In some embodiments, a bonding interface forms between the layer of insulating oxide 14 and the layer of boron nitride 16. In other embodiments, a bonding interface forms between an uppermost surface of the handle substrate 12 and the layer of boron nitride 16.

Bonding is achieved in the present disclosure by first bringing the two structures shown in FIG. 11 into intimate contact with other, optionally applying an external force to the contacted structures, and annealing the two contacted structures under conditions that are capable of increasing the bonding energy between the two structures, i.e., between the layer of insulating oxide 14 and the layer of boron nitride 16 or between the uppermost surface of the handle substrate 12 and the layer of boron nitride 16. The annealing that is employed for bonding may be performed in the presence or absence of an external force. In one embodiment, bonding is achieved at an elevated temperature of from 150° C. to 250° C. In another embodiment, bonding is achieved at an elevated temperature of from 250° C. to 350° C.

After bonding, and in some embodiments, the bonded structure can be further annealed to enhance the bonding strength and improve the interface property. The further anneal, which may be referred to as a first post-bonding anneal, can be performed at a temperature from 150° C. to 350° C. The first post-bonding anneal can performed within the aforementioned temperature range for various time periods that may range from 1 hour to 24 hours. The first post-bonding anneal ambient can be O₂, N₂, Ar, or a low vacuum, with or without external adhesive forces. Mixtures of the aforementioned annealing ambients, with or without an inert gas, are also contemplated herein.

In some embodiments in which the semiconductor wafer 20′ of the bonded structure includes hydrogen implant region 24, the hydrogen implant region 24 forms a porous region which causes a portion of the semiconductor wafer 20′ above the implant region 24 to break off during a subsequent anneal leaving an SOI layer 20 such as is shown, for example, in FIG. 13. This layer splitting process typically occurs by annealing at a temperature from 300° C. to 550° C. This anneal, which may be referred to a second post-bonding anneal, is typically performed in N₂.

In some embodiments of the present disclosure, a yet further anneal can be performed at an elevated temperature to further enhance bonding between the layer of insulating oxide 14 and the boron nitride layer 16 as well as between the handle substrate 12 and the layer of boron nitride 16. This yet further anneal which can be referred to a third post-bonding anneal can be performed at a temperature from 800° C. to 1050° C. The third post-bonding anneal can be performed within the aforementioned temperature range for various time periods that may range from 1 hour to 24 hours. The third post-bonding anneal ambient can be O₂, N₂, Ar, or a low vacuum, with or without external adhesive forces. Mixtures of the aforementioned annealing ambients, with or without an inert gas, are also contemplated herein.

In some embodiments, the SOI layer 20 or the semiconductor wafer 20′ can be thinned by subjecting the bonded structure to planarization. This step can also be employed in the absence of a hydrogen implant region being formed into the semiconductor wafer 20′ to provide the structure shown, for example, in FIG. 13. The planarization that can be used includes, for example, chemical mechanical polishing and/or grinding. This provides an SOI structure in which the resultant SOI layer has a thickness within the ranges that were previously mentioned herein for the SOI layer 20.

Referring now to FIG. 14, there is illustrated the structure of FIG. 13 after removing selective portions of SOI layer 20 forming at least one SOI mesa 22. The removing of selective portions of the SOI layer 20 can be performed by lithography and etching. The lithographic step includes forming a photoresist atop the SOI layer, exposing the photoresist to a pattern of irradiation, and developing the exposed photoresist utilizing a conventional resist developer. The etching step includes a wet chemical etch process, a dry etch (reactive ion etching, plasma etching, ion beam etching or laser ablation) process or any combination thereof.

The SOI structures shown in FIGS. 13 and 14 can be used in forming various semiconductor devices including, but not limited to, FETs, FinFETs, and nanowire FETs. The various semiconductor devices can abut the SOI layer or the at least one SOI mesa. In some embodiments, the semiconductor device is located in, and upon, the SOI layer. In other embodiments, the semiconductor devices are located in and upon exposed surfaces (sidewall and optionally uppermost surfaces) of each SOI mesa. The various semiconductor devices that can be formed include materials that are well known to those skilled in the art and such semiconductor devices can be formed utilizing processing techniques that are well known to those skilled in the art. Detailed concerning the materials of the semiconductor devices and the methods used in forming the same are not provided herein so as not to obscure the various embodiments of the present disclosure.

While the present disclosure has been particularly shown and described with respect to various embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A method of forming a semiconductor-on-insulator (SOI) structure comprising:
providing a handle substrate comprising a first semiconductor material;
providing a layer of boron nitride atop a surface of a semiconductor wafer comprising a second semiconductor material;
bonding the handle substrate to the layer of boron nitride to provide a bonded structure in which the semiconductor wafer represents a topmost layer of the bonded structure and the handle represents a bottommost layer of the bonded substrate; and
removing a portion of the semiconductor wafer to provide a semiconductor-on-insulator (SOI) layer of a silicon-on-insulator (SOI) structure, said SOI structure comprising said handle substrate, said layer of boron nitride located on an uppermost surface of the handle substrate and said SOI layer located atop the layer of boron nitride.

2. The method of claim 1, further comprising providing a layer of insulating oxide between said layer of boron nitride and said semiconductor wafer.

3. The method of claim 2, further comprising removing a portion of said SOI layer forming at least one SOI mesa atop said layer of insulating oxide.

4. The method of claim 1, further comprising removing a portion of said SOI layer forming at least one SOI mesa atop said layer of boron nitride.

5. The method of claim 1, further comprising forming a hydrogen implant region in said second semiconductor wafer after forming said layer of boron nitride atop said semiconductor wafer and prior to bonding.

6. The method of claim 2, further comprising forming a hydrogen implant region in said second semiconductor wafer after forming said layer of insulating oxide layer and said layer of boron nitride atop said semiconductor wafer and prior to bonding.

7. The method of claim 1, wherein said bonding comprises bringing the handle substrate and the layer of boron nitride into intimate contact with other, and annealing at an elevated temperature of from 150° C. to 1050° C.

8. The method of claim 1, wherein said providing the layer of boron nitride atop the surface of the semiconductor wafer comprising the second semiconductor material includes annealing at a temperature from 900° C. to 1250° C. in an oxygen free ambient, and planarizing the layer of boron nitride to provide an uppermost surface having a roughness of less than 5 Å.

9. The method of claim 7, further comprising subjecting the bonded to structure to a first post-bonding anneal at a temperature from 150° C. to 350° C.

10. The method of claim 7, further comprising subjecting the bonded structure to a second-post anneal, at a temperature from 300° C. to 550° C., to cause splitting of the semiconductor wafer at a hydrogen-implant region located in said semiconductor wafer.

11. The method of claim 8, further comprising subjecting the bonded structure to a third-post anneal at a temperature from 800° C. to 1050° C.

12. The method of claim 11, further comprising subjecting remaining portions of the semiconductor wafer to a planarization process.

13. A method of forming a semiconductor-on-insulator (SOI) structure comprising:
providing a layer of insulating oxide on a surface of a handle substrate comprising a first semiconductor material;
providing a layer of boron nitride atop a surface of a semiconductor wafer comprising a second semiconductor material;
bonding the layer of insulating oxide to the layer of boron nitride to provide a bonded structure in which the semiconductor wafer represents a topmost layer of the bonded structure and the handle represents a bottommost layer of the bonded substrate; and
removing a portion of the semiconductor wafer to provide a semiconductor-on-insulator (SOI) layer of a silicon-on-insulator (SOI) structure, said SOI structure comprising said handle substrate, said layer of insulating oxide located on an uppermost surface of the handle substrate, said layer of boron nitride located on an uppermost surface of the layer of insulating oxide and said SOI layer located atop the layer of boron nitride.

14. The method of claim 13, further comprising providing another layer of insulating oxide between said layer of boron nitride and said semiconductor wafer.

15. The method of claim 13, further comprising removing a portion of said SOI layer forming at least one SOI mesa atop said another layer of insulating oxide.

16. The method of claim 13, further comprising removing a portion of said SOI layer forming at least one SOI mesa atop said layer of boron nitride.
